(19) United States
(12) Patent Application Publication
(10) Pub. No.: US 2016/0260805 A1
(43) Pub. Date: Sep. 8, 2016

(54) GERMANIUM-ON-INSULATOR SUBSTRATE AND METHOD FOR FORMING THE SAME

(71) Applicant: ELECTRONICS AND TELECOMMUNICATIONS RESEARCH INSTITUTE, Daejeon (KR)

(72) Inventors: Sang Hoon KIM, Daejeon (KR); Gyungock KIM, Daejeon (KR); In Gyoo KIM, Daejeon (KR)

(21) Appl. No.: 15/056,660

(22) Filed: Feb. 29, 2016

(30) Foreign Application Priority Data
Mar. 3, 2015 (KR) 10-2015-0029812

(51) Int. Cl. H01L 29/161; H01L 21/3105; H01L 21/02; H01L 29/06; H01L 21/311

(52) U.S. Cl. CPC H01L 29/161; H01L 29/0649; H01L 21/31111; H01L 21/02532; H01L 21/0262; H01L 21/31056

(57) ABSTRACT

Provided is a germanium-on-insulator substrate. The germanium-on-insulator substrate includes a bulk silicon substrate, an oxide film which is disposed on the bulk silicon substrate and has a first region exposing a portion of the bulk silicon substrate, a silicon layer which covers a portion of the top surface of the oxide film and does not cover the first region, a germanium layer which contacts the bulk silicon substrate exposed through the first region and is disposed on the oxide film, and an insulating layer which covers the oxide film and the silicon layer and exposes the top surface of the germanium layer.

### CROSS-REFERENCE TO RELATED APPLICATIONS

This U.S. non-provisional patent application claims priority under 35 U.S.C. §119 of Korean Patent Application No. 10-2015-0029812, filed on Mar. 3, 2015, the entire contents of which are hereby incorporated by reference.

### BACKGROUND

The present disclosure herein relates to a semiconductor, and particularly, to a germanium-on-insulator substrate and a method for forming the same.

With the rapid development of the mobile communication industry, demands for ultra-high speed, ultra-high integration, and low power of performance of information communication devices are increasing. Accordingly, a silicon-on-insulator (SOI) substrate is being used as a substrate for a semiconductor device.

Recently, researches on a germanium-on-insulator (GeOI) substrate are being carried out in order to use the properties of germanium which has excellent electron and hole mobility as compared to silicon.

### SUMMARY

The present disclosure provides a germanium-on-insulator substrate. The germanium-on-insulator substrate includes a bulk silicon substrate, an oxide film which is disposed on the bulk silicon substrate and has a first region exposing a portion of the bulk silicon substrate, a silicon layer which covers a portion of atop surface of the oxide film and exposes the first region, a germanium layer which contacts the bulk silicon substrate exposed through the first region and is disposed on the oxide film, and an insulating layer which covers the oxide film and the silicon layer and exposes a top surface of the germanium layer.

In an embodiment, the silicon layer and the germanium layer may be disposed to be spaced apart from each other.

In an embodiment, the germanium layer may include a growth layer which fills the first region and contacts the bulk silicon substrate, and a germanium single crystal layer which is connected to the growth layer and is disposed on the oxide film.

In an embodiment, the germanium single crystal layer may have the same thickness as the insulating layer.

In an embodiment, the oxide film may have a second region recessed toward the bulk silicon substrate.

In an embodiment, the thickness of the germanium single crystal layer may be larger than the thickness of the insulating layer.

In an embodiment, the top surface of the insulating layer and the top surface of the germanium layer may be at the same level.

In an embodiment, the first region may have a width along a first direction parallel to a top surface of the bulk silicon substrate and a height along a second direction perpendicular to the first direction, and the width of the first region may be less than the height of the first region.

The present invention provides a germanium-on-insulator substrate according to another embodiment. The germanium-on-insulator substrate includes a bulk silicon substrate, an oxide film which is disposed on the bulk silicon substrate and has a first region exposing a portion of the bulk silicon substrate and a second region recessed toward the bulk silicon substrate, a silicon layer covering a portion of a top surface of the oxide film, a germanium layer grown onto the oxide film using the bulk silicon substrate exposed through the first region as a seed layer, and an insulating layer disposed on the silicon layer, and the germanium layer contacts the silicon layer.

In an embodiment, the germanium layer may include a growth layer which fills the first region and contacts the bulk silicon substrate, and a germanium single crystal layer which is connected to the growth layer and is grown onto the oxide film.

In an embodiment, the thickness of the germanium single crystal layer may be larger than the sum of the thicknesses of the insulating layer and the silicon layer.

In an embodiment, a top surface of the insulating layer and a top surface of the germanium single crystal layer may be disposed on the same plane.

The present invention provides a method for forming a germanium-on-insulator substrate. The method for forming a germanium-on-insulator substrate includes stacking an oxide film and a silicon layer in sequence on the bulk silicon substrate, etching a portion of the silicon layer to expose a portion of the oxide film, forming an insulating layer covering both the silicon layer and the exposed oxide film, etching a portion of the insulating layer to expose a top surface of the oxide film, etching the oxide film to expose a portion of the bulk silicon substrate, and forming a germanium layer which is grown from the exposed bulk silicon substrate and is disposed on the oxide film.

In an embodiment, the etching of the portion of the insulating layer may include etching the insulating layer so as to form an etching width less than a width exposed by etching the silicon layer.

In an embodiment, the etching of the oxide film may include etching a portion of the oxide film to form a first region exposing a portion of the bulk silicon substrate, and the height of the first region may be larger than the width of the first region.

In an embodiment, the method may further include forming a second region having an etching width larger than a width exposed by etching the oxide film, after the etching of the portion of the insulating layer.

In an embodiment, the forming of the germanium layer may include growing the germanium single crystal layer in the second region up to the same level as the top surface of the oxide film, etching the insulating layer such that a side surface of the silicon layer and a side surface of the insulating layer are disposed on the same plane, and growing the germanium single crystal layer at least up to the top surface of the insulating layer.

In an embodiment, the method may further include performing chemical mechanical polishing such that the top surface of the insulating layer and a top surface of the germanium single crystal layer are disposed at the same level.

In an embodiment, the forming of the germanium layer may include depositing the germanium layer using a reduced pressure chemical vapor deposition process (RPCVD) or an ultra-high vacuum chemical vapor deposition (UHVCVD).

In an embodiment, the forming of the germanium layer may include depositing the germanium layer at a deposition temperature between 400° C. and 700° C. using a mixed gas of GeH₄ and H₂, and the flow rate of the mixed gas of GeH₄ and H₂ is 10 sccm to 100 sccm.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a sectional view illustrating a germanium-on-insulator substrate according to an embodiment of the inventive concept;

FIGS. 2A to 2G are sectional views illustrating a method for forming the germanium-on-insulator substrate in FIG. 1;

FIG. 3 is a sectional view illustrating a germanium-on-insulator substrate according to another embodiment of the inventive concept;

FIGS. 4A to 4D are sectional views illustrating a method for forming the germanium-on-insulator substrate in FIG. 3;

FIG. 5 is a sectional view illustrating a germanium-on-insulator substrate according to an embodiment of the inventive concept; and

FIGS. 6A to 6F are sectional views illustrating a method for forming the germanium-on-insulator substrate in FIG. 5.

### DETAILED DESCRIPTION

Hereinafter, preferred embodiments of the inventive concept will be described with reference to the accompanying drawings to fully explain the inventive concept in such a manner that it may be easily carried out by those skilled in the art.

Advantages and features of the present invention, and implementation methods thereof will be clarified through the following embodiments described with reference to the accompanying drawings. The present invention may, however, be embodied in different forms and should not be construed as being limited to the embodiments set forth herein. Rather, these embodiments are provided to complete the disclosure of the present invention and fully convey the scope of the invention to those skilled in the art. Further, the present invention is only defined by the scope of claims. Like reference numerals or symbols refer to like elements throughout.

Additionally, the embodiments in the detailed description will be described with reference to sectional views and/or plan views as ideal exemplary views of the present invention. In the figures, the dimensions of layers and regions are exaggerated for effective description of the technical contents. Accordingly, the exemplary views may be modified according to manufacturing techniques and/or allowable errors. Thus, the embodiments of the present invention are not limited to specific forms illustrated, but may include other forms that may be created according to manufacturing processes. For example, an etched region illustrated as a rectangle may have rounded or curved features. Therefore, regions illustrated in the drawings have general properties, and the shapes thereof are not intended to limit the scope of the invention, but are used to illustrate a specific form of region in a device.

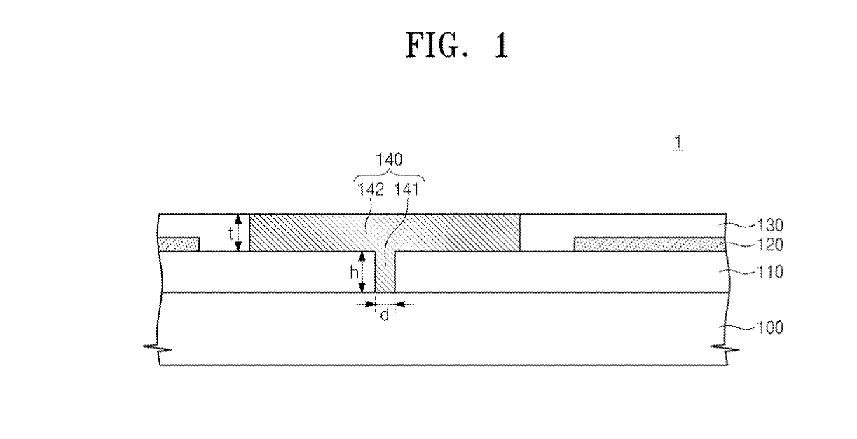

FIG. 1 is a sectional view illustrating a germanium-on-insulator substrate according to an embodiment of the inventive concept.

Referring to FIG. 1, a germanium-on-insulator 1 may include a bulk silicon substrate 100, an oxide film 110, a silicon layer 120, an insulating layer 130, and a germanium layer 140. On the bulk silicon substrate 100, the oxide film 110 exposing a portion of the bulk silicon substrate 100 may be disposed. On the oxide film 110, the silicon layer 120 may be disposed. The silicon layer 120 may cover a portion of the oxide film 110. The bulk silicon substrate 100, the oxide film 110, and the silicon layer 120 may constitute a silicon-on-insulator (SOI) structure. The germanium layer 140 may include a growth layer 141 contacting the exposed bulk silicon substrate 100, and a germanium single crystal layer 142 which is connected to the growth layer 141 and is disposed on the oxide film 110. The germanium layer 140 may be disposed to be spaced apart from the silicon layer 120. The width d of the growth layer 141 may be smaller the height h of the growth layer 141. The germanium single crystal layer 142 may have the same thickness as the insulating layer 130. For example, the thickness t of the germanium single crystal layer 142 may be a few μm. The insulating layer 130 may be disposed so as to cover the oxide film 110 and the silicon layer 120 and expose the top surface of the germanium layer 140. The insulating layer 130 may include an oxide, a nitride, an oxynitride, or a mixture thereof. The thickness t of the germanium single crystal layer 142 may be determined by adjusting the thickness of the insulating layer 130. The top surface of the insulating layer 130 and the top surface of the germanium layer 140 may be at the same level.

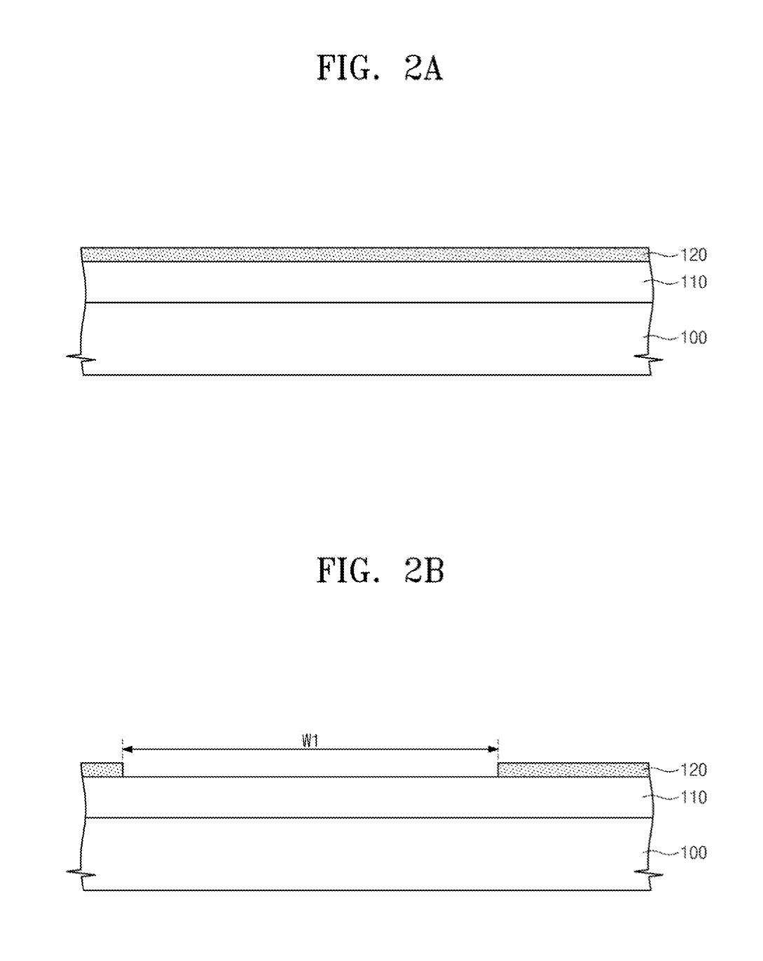

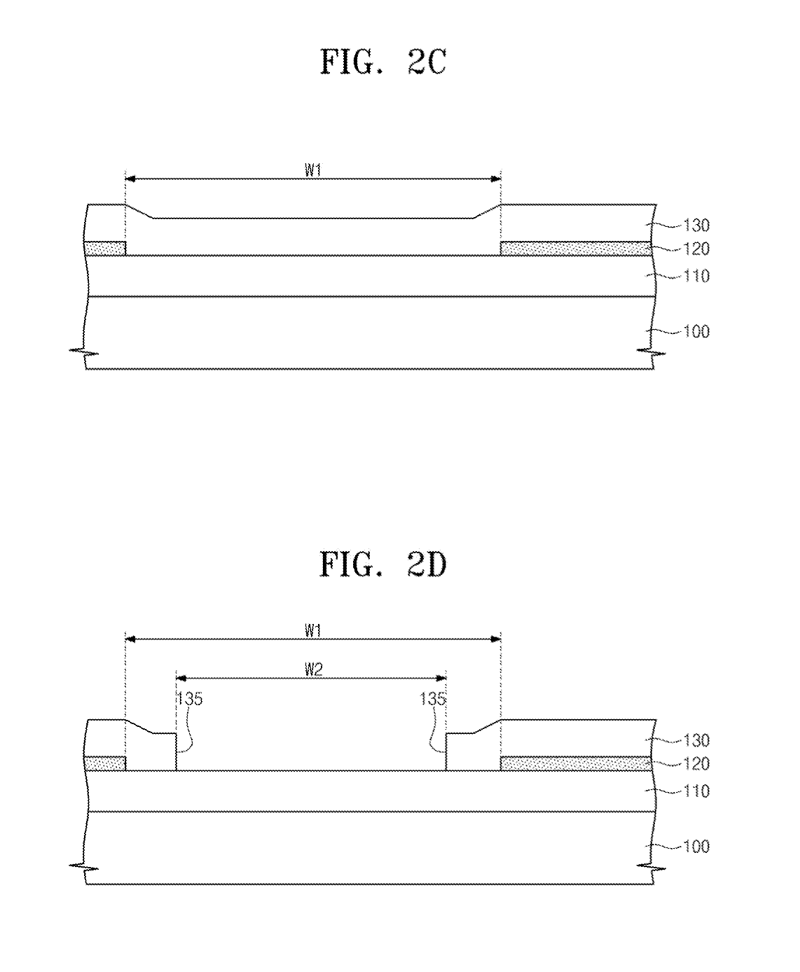

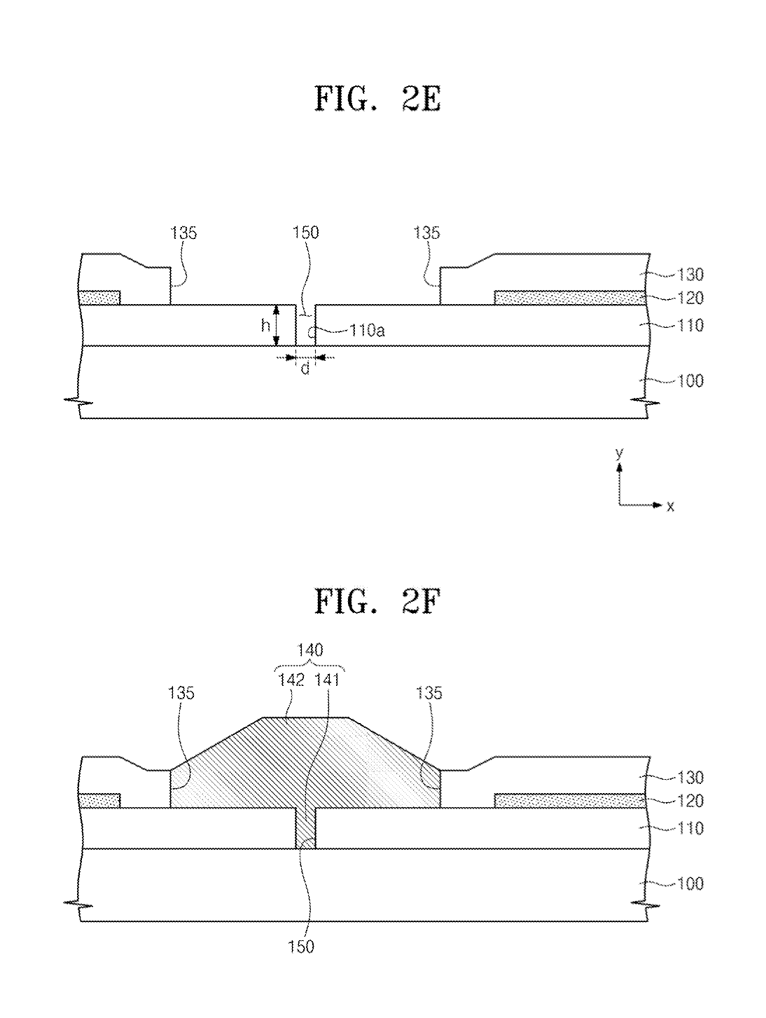

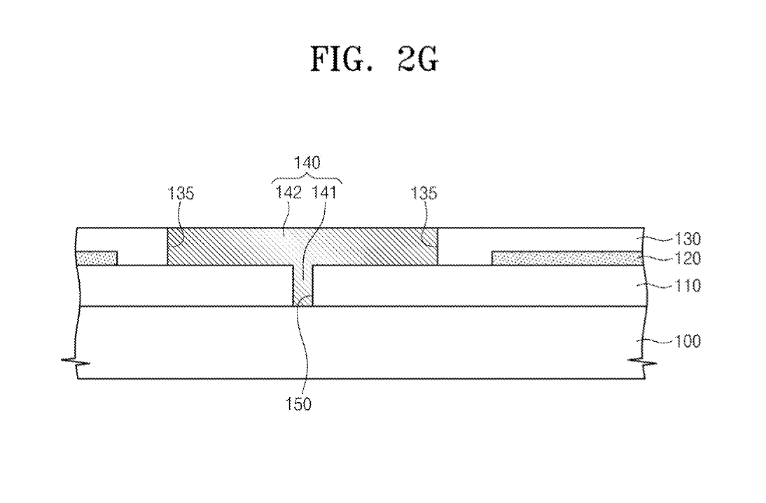

FIGS. 2A to 2G are sectional views illustrating a method for forming the germanium-on-insulator substrate in FIG. 1.

Referring to FIG. 2A, on the bulk silicon substrate 100, the oxide film 110 and the silicon layer 120 may be formed in sequence. The bulk silicon substrate 100, the oxide film 110, and the silicon layer 120 may constitute a silicon-on-insulator (SOI) structure.

Referring to FIG. 2B, in order to form a germanium-on-insulator (GeOI) structure in a certain region in the silicon-on-insulator (SOI) structure, a portion W1 of the silicon layer 120 may be etched. A portion of the top surface of the oxide film 110 may be exposed by partially etching the silicon layer 120.

Referring to FIG. 2C, the insulating layer 130 covering both the silicon layer 120 and the exposed oxide film 110 may be formed. The insulating layer 130 may be formed by depositing an oxide, a nitride, an oxynitride, or a mixture thereof.

Referring to FIG. 2D, the insulating layer 130 may be dry-etched to expose a portion of the top surface of the oxide film 110. When an etched region W2 of the insulating layer 130 is the same as or wider than the region W1 exposed by etching the silicon layer 120, the silicon layer 120 may be exposed. When the silicon layer 120 is exposed, both the exposed bulk silicon substrate 100 and silicon layer 120 may serve as a seed layer during the growth of the germanium layer 140, which will be later described in FIG. 2F. This may result in defects in a region in which the germanium layer 140 and the silicon layer 120 contact with each other. In order to prevent such defects, the insulating layer 130 may be etched such that the silicon layer 120 is not exposed. In other words, the etched region W2 of the insulating layer 130 may be smaller than the etched region W1 of the silicon layer 120. The width of the etched region W2 of the insulating layer 130 may be smaller than the width of the etched region W1 by about 1.0 μm or more. That is, there may be a gap of about 0.1 μm to 0.5 μm between one side of the etched region W1 of the silicon layer 120 and one side of the etched region W2 of the insulting layer 130 adjacent thereto. Both sidewalls 135 of the insulating layer 130 may be formed by etching.

Referring to FIG. 2E, the oxide film 110 may be etched to expose a portion of the bulk silicon substrate 100. The exposed region of the bulk silicon substrate 100 may be defined as a first region 150. The first region 150 may have a width d along a first direction x parallel to the top surface of the bulk silicon substrate 100 and a height h along a second direction y perpendicular to the first direction x. Both sidewalls 110a of the oxide film 110 may be formed by etching the oxide film 110. The sidewalls 110a of the oxide film 110 may have the same height as the height h of the first region 150.

Referring to FIG. 2F, the germanium layer 140 may be formed using the bulk silicon substrate 100 exposed by the first region 150 as a seed layer. The germanium layer 140 may be grown until the top of the germanium layer 140 reaches a level higher than the top surface of the insulating layer 130. A crystal face of the germanium layer 140 may extend from the top surface of the insulating layer 130.

The germanium layer 140 may be formed to be spaced apart from the silicon layer 120. The germanium layer 140 may be divided into the growth layer 141 filling the first region 150, and the germanium single crystal layer 142 disposed on the oxide film 110. The germanium single crystal layer 142 may contact the sidewalls 135 of the insulating layer 130. The forming of the germanium layer 140 may include depositing the germanium layer 140 using a reduced pressure chemical vapor deposition process (RPCVD) or an ultra-high vacuum chemical vapor deposition (UHVCVD). The growth of the germanium layer 140 may be performed under the process conditions of a temperature range of 400° C. to 700° C. and a pressure range of several tens of Torr. A GeH₄ gas diluted to 5-30% in H₂ may be used as a supply gas for depositing the germanium layer 140, and a hydrogen gas may be used as a carrier gas. The flow rate of the supply gas may be 10 sccm to 100 sccm, and the flow rate of the carrier gas may be 10 slm to 50 slm.

The first region 150 may serve to limit threading dislocation, which is generated at the interface between the bulk silicon substrate 100 and the germanium layer 140 during the growth of the germanium layer 140 described in FIG. 2F, to the sidewalls of the oxide film 110. That is, due to the first region 150, the germanium single crystal layer 142 may not be affected by threading dislocation generated between the growth layer 141 and the bulk silicon substrate 100. Therefore, the dislocation density of the germanium layer 140 may be reduced, and during epitaxial lateral overgrowth (ELO) of germanium onto the oxide film 110, a high quality germanium layer 140 may be obtained.

The silicon layer 120 may be covered by the insulating layer 130, and may thus not be exposed. Accordingly, the germanium layer 140 may be grown from the bulk silicon substrate 100 exposed by the first region 150.

Referring to FIG. 2G, chemical mechanical polishing (CMP) may be performed such that top surfaces of the insulating layer 130 and the germanium layer 140 are disposed at the same level. By disposing top surfaces of the insulating layer 130 and the germanium layer 140 on the same plane, an optical communication device or a device such as a complementary MOSFET (C-MOSFET) may be easily integrated on the insulating layer 130 and the germanium layer 140. The germanium single crystal layer 142 may have the same thickness as the insulating layer 130. Therefore, the thickness of the germanium single crystal layer 142 may depend on the thickness of the insulating layer 130.

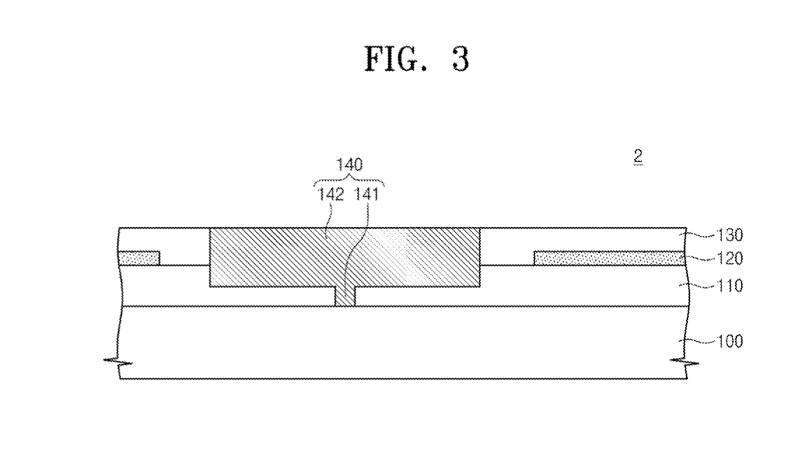

FIG. 3 is a sectional view illustrating a germanium-on-insulator substrate according to another embodiment of the inventive concept. For simplicity in description, a redundant description will be omitted.

Referring to FIG. 3, a germanium-on-insulator substrate 2 may include the bulk silicon substrate 100, the oxide film 110, the silicon layer 120, the insulating layer 130, and the germanium layer 140. The germanium layer 140 may include the growth layer 141 contacting the bulk silicon substrate 100, and the germanium single crystal layer 142 which is connected to the growth layer 141 and is disposed on the oxide film 110. A portion of the oxide film 110 may be recessed toward the bulk silicon substrate 100. Since the portion of the oxide film 110 is recessed, the germanium single crystal layer 142 may have a thickness larger than the thickness of the insulating layer 130. The germanium layer 140 may be disposed to be spaced apart from the silicon layer 120.

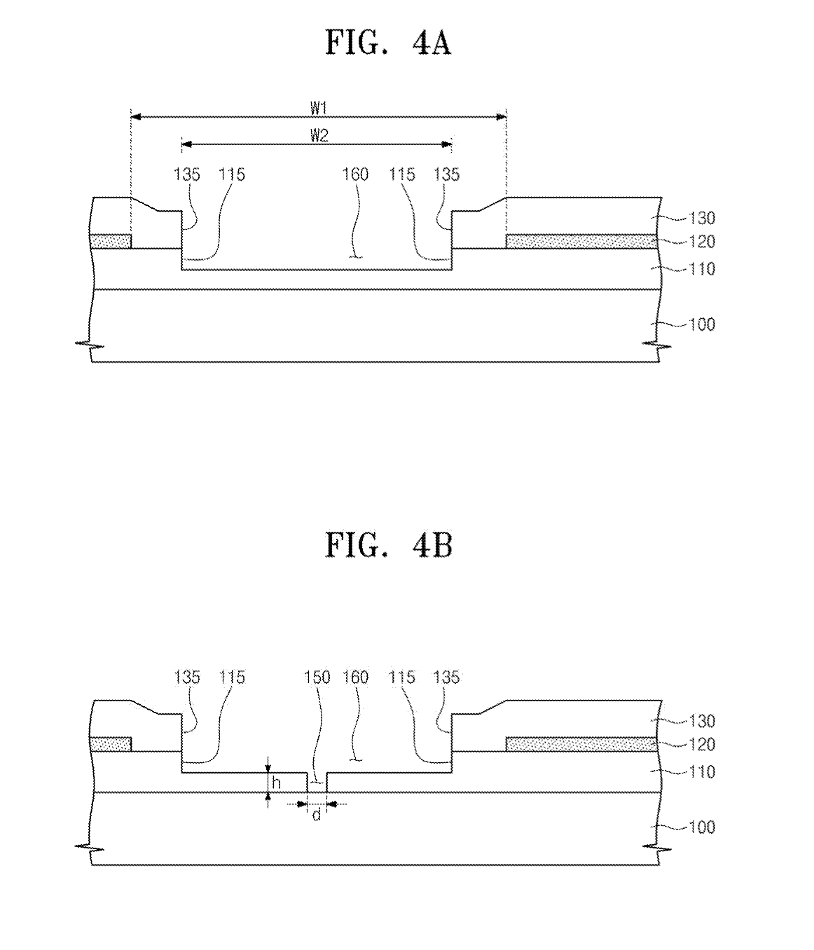

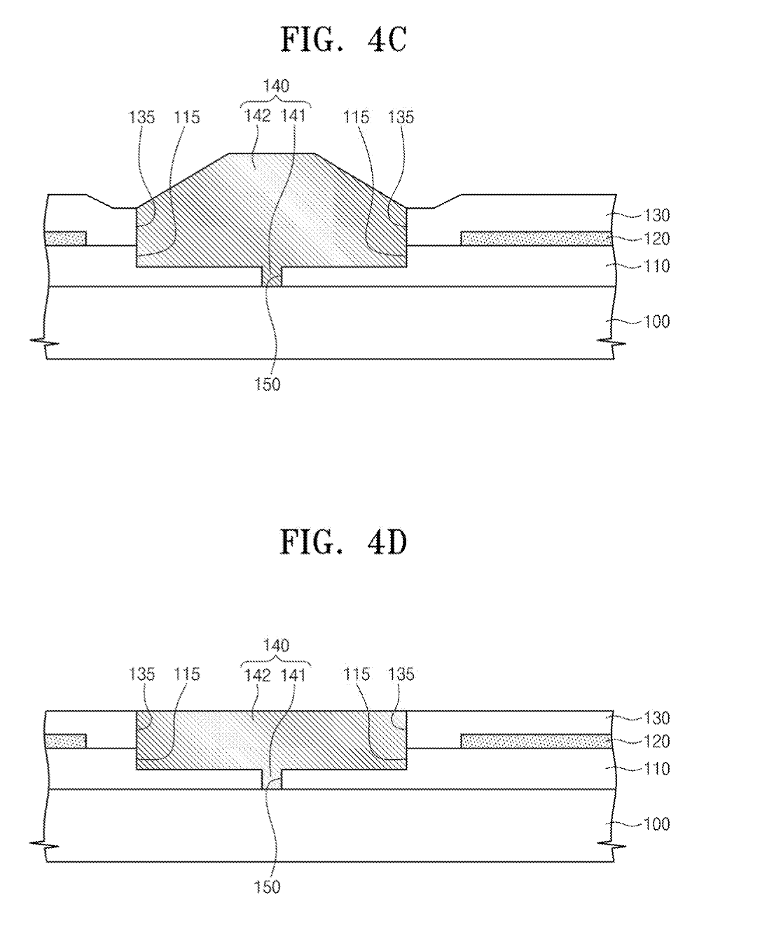

FIGS. 4A to 4D are sectional views illustrating a method for forming the germanium-on-insulator substrate in FIG. 3. FIGS. 4A to 4D illustrate processes after the processes in FIGS. 2A to 2C. For simplicity in description, a redundant description will be omitted.

Referring to FIG. 4A, the insulating layer 130 and the oxide film 110 may be etched. The insulating layer 130 and the oxide film 110 may be etched so as to have an etching width W2 smaller than a width W1 exposed by etching the silicon layer 120. In other words, even if the insulating layer 130 and the oxide film 110 are etched, the silicon layer 120 may not be exposed. The etched portion of the oxide film 110 may be defined as a second region 160. By the etching, both sidewalls 115 of the oxide film 110 and both sidewalls 135 of the insulating layer 130 may be formed.

Referring to FIG. 4B, the oxide film 110 may be dry-etched to expose a portion of the bulk silicon substrate 100. An exposed first region 150 of the bulk silicon substrate 100 may be connected to the second region 160. The width d of the first region 150 may be smaller than the height h of the first region 150.

Referring to FIG. 4C, the germanium layer 140 may be grown using the bulk silicon substrate 100 exposed by the first region 150 as a seed layer. Since the silicon layer 120 is covered by the insulating layer 130, the germanium layer 140 may be grown from the bulk silicon substrate 100, but not from the silicon layer 120. The germanium layer 140 may be grown until the top of the germanium layer 140 reaches a level higher than the top surface of the insulating layer 130. The germanium layer 140 may be grown to be spaced apart from the silicon layer 120, and a crystal face of the germanium layer 140 may extend from the top surface of the insulating layer 130. The growth layer 141 of the germanium layer 140 may fill the first region 150, and the germanium single crystal layer 142 of the germanium layer 140 may fill the second region 160. The germanium single crystal layer 142 may contact the sidewalls 115 of the oxide film 110 and the sidewalls 135 of the insulating layer 130.

Referring to FIG. 4D, chemical mechanical polishing (CMP) may be performed such that top surfaces of the insulating layer 130 and the germanium layer 140 are disposed at the same level. Accordingly, the germanium single crystal layer 142 may have a thickness larger than the thickness of the insulating layer 130. The thickness of the germanium single crystal layer 142 may be determined by adjusting the thickness of the insulating layer 130 and the etching thickness of the second region 160 (FIG. 4B).

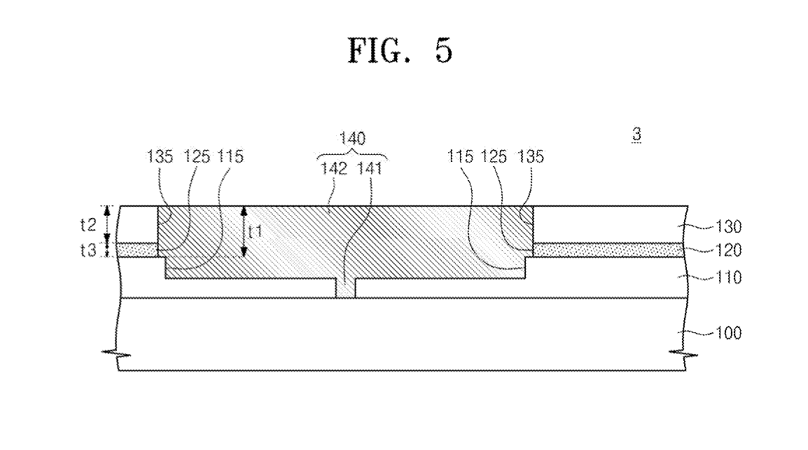

FIG. 5 is a sectional view illustrating a germanium-on-insulator substrate according to an embodiment of the inventive concept. For simplicity in description, a redundant description will be omitted.

Referring to FIG. 5, a germanium-on-insulator substrate (3) may include the bulk silicon substrate 100, the oxide film 110, the silicon layer 120, the insulating layer 130, and the germanium layer 140. A portion of the oxide film 110 may be recessed toward the bulk silicon substrate 100. Since the portion of the oxide film 110 is recessed, the thickness t1 of the germanium single crystal layer 142 may be larger than the sum of the thickness t2 of the insulating layer 130 and the thickness t3 of the silicon layer 120. The sidewalls 115 of the oxide film 110 may be more adjacent to the growth layer 141 of the germanium layer 140 as compared to sidewalls 125 of the silicon layer 120, and the sidewall 135 of the insulating layer 130 may be vertically aligned with the sidewall 125 of the silicon layer 120. In an alternative example, the sidewall 115 of the oxide film 110, the sidewall 125 of the silicon layer 120, and the sidewall 135 of the insulating layer 130 may be vertically aligned with each other. The germanium single crystal layer 142 may contact the sidewalls 115 of the oxide film 110, the sidewalls 125 of the silicon layer 120, and the sidewalls 135 of the insulating layer 130.

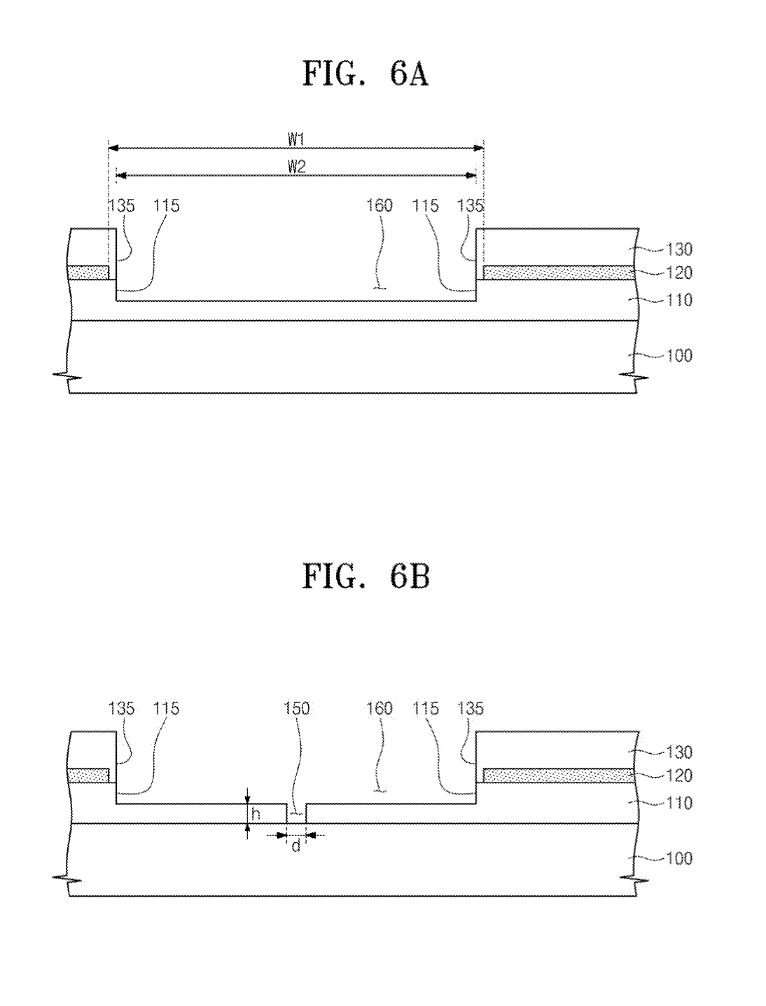

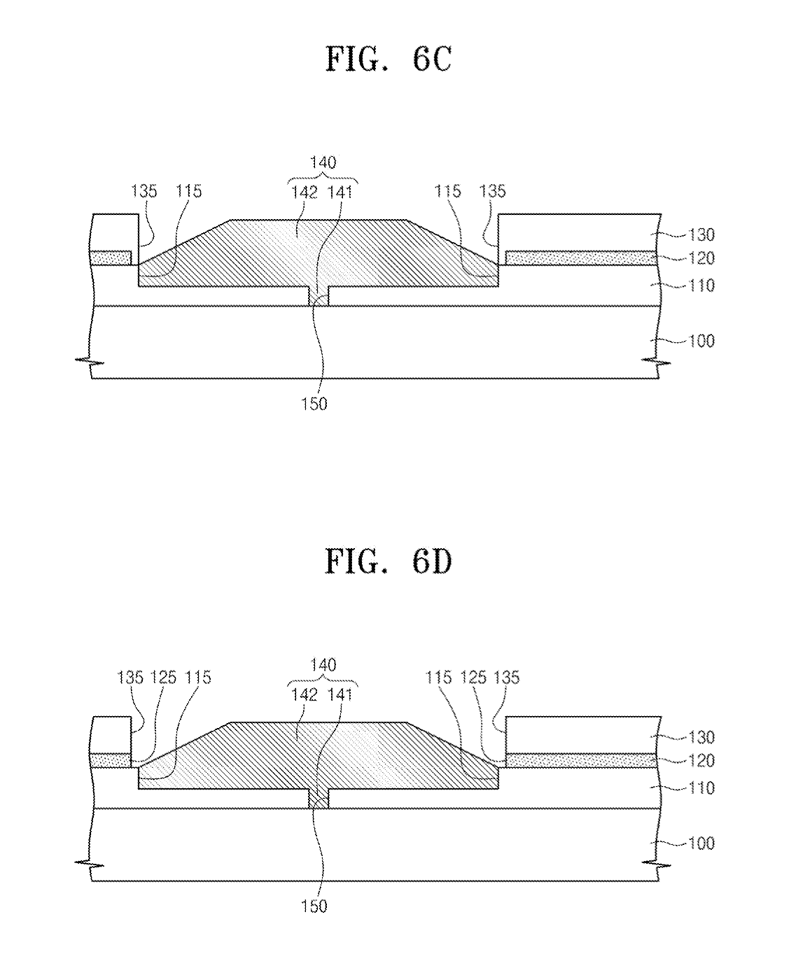

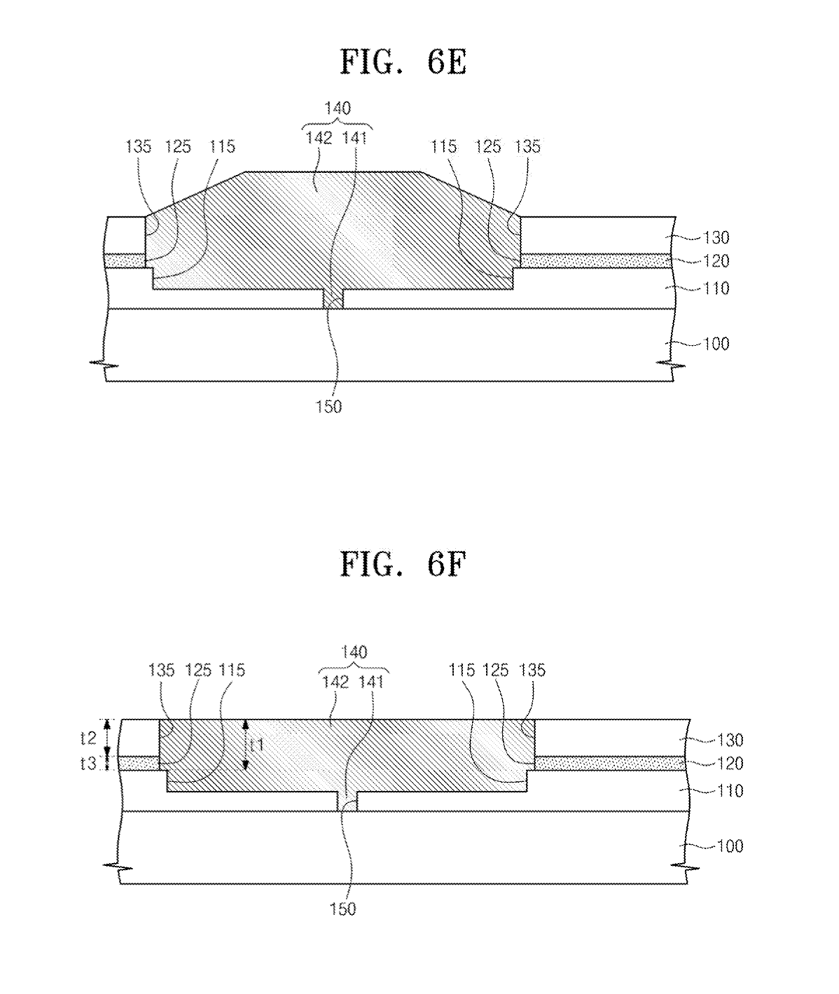

FIGS. 6A to 6F are sectional views illustrating a method for forming the germanium-on-insulator substrate in FIG. 5. FIGS. 6A to 6F illustrate processes after the processes in FIGS. 2A to 2C. For simplicity in description, a redundant description will be omitted.

Referring to FIG. 6A, the insulating layer 130 and the oxide film 110 may be dry-etched. The insulating layer 130 and the oxide film 110 may be etched so as to have an etching width W2 smaller than a width W1 exposed by etching the silicon layer 120. A sidewall 135 of the insulating layer 130 and a sidewall 115 of the oxide film 110, the sidewalls being formed by the etching, may be vertically aligned with each other. The etched portion of the oxide film 110 may be defined as a second region 160.

Referring to FIG. 6B, a first region 150 exposing the bulk silicon substrate 100 may be formed under the second region 160. The oxide film 110 may be dry-etched such that the width d of the first region 150 is smaller than the height h of the first region 150.

Referring to FIG. 6C, the germanium layer 140 may be grown using the bulk silicon substrate 100 exposed by the first region 150 as a seed layer. The germanium layer 140 may be grown up to the same level as the top surface of the oxide 110. The growth layer 141 may fill the first region 150, and the germanium single crystal layer 142 may fill the second region 160. The germanium single crystal layer 142 may contact the sidewalls 115 of the oxide film 110.

Referring to FIG. 6D, the insulating layer 130 may be wet-etched to expose the silicon layer 120. The insulating layer 130 may be etched as much as the distance between the sidewall 135 of the insulating layer 130 and the silicon layer 120. For example, the distance between the sidewall 135 of the insulating layer 130 and the silicon layer 120 may be 0.1 μm to 0.5 μm. Both sidewalls 125 of the silicon layer 120 may be exposed by etching.

Referring to FIG. 6E, the germanium layer 140 may be grown subsequently. The germanium layer 140 may be grown until the top of the germanium layer 140 reaches a level higher than the top surface of the insulating layer 130. A crystal face of the germanium layer 140 may extend from the top surface of the insulating layer 130. The germanium layer 140 may contact the sidewalls 115 of the oxide film 110, the sidewalls 125 of the silicon layer 120, and the sidewalls 135 of the insulating layer 130.

Referring to FIG. 6F, chemical mechanical polishing (CMP) may be performed such that top surfaces of the insulating layer 130 and the germanium layer 140 are disposed at the same level. Accordingly, the thickness t1 of the germanium single crystal layer 142 may be larger than the sum of the thickness t2 of the insulating layer 130 and the thickness t3 of the silicon layer 120. The thickness t1 of the germanium single crystal layer 142 may be determined by adjusting the thickness t2 of the insulating layer 130 and the etching thickness of the second region 160 (FIG. 6B).

In contrast to the above description, the germanium layer 140 may have the same thickness as the insulating layer 130, while the silicon layer 120 and the germanium layer 140 contacting with each other. Whether the silicon layer 120 and the germanium layer 140 contact with each other, and the thickness of the germanium layer 140 may be determined in various ways.

According to a preferred embodiment of the inventive concept, a germanium-on-insulator and a silicon-on-insulator may be formed using a bulk silicon substrate.

According to a preferred embodiment of the inventive concept, the thickness of a germanium layer may be controlled according to a method for a germanium-on-insulator.

Although specific embodiments are described in the detailed description, various modifications can be made without departing from the scope and spirit of the invention. Therefore, the scope of the invention should not be defined by the above described embodiments, but should be determined by the accompanying claims as well as equivalents of the claims of the invention.

What is claimed is:

1. A germanium-on-insulator substrate comprising:
a bulk silicon substrate;
an oxide film disposed on the bulk silicon substrate, the oxide film having a first region exposing a portion of the bulk silicon substrate;
a silicon layer covering a portion of a top surface of the oxide film and exposing the first region;
a germanium layer in contact with the bulk silicon substrate exposed through the first region, the germanium layer disposed on the oxide film; and
an insulating layer covering the oxide film and the silicon layer and exposing a top surface of the germanium layer.

2. The germanium-on-insulator substrate of claim 1, wherein the silicon layer and the germanium layer are disposed to be spaced apart from each other.

3. The germanium-on-insulator substrate of claim 1, wherein the germanium layer comprises:
a growth layer filling the first region and contacting the bulk silicon substrate; and
a germanium single crystal layer connected to the growth layer and disposed on the oxide film.

4. The germanium-on-insulator substrate of claim 3, wherein the germanium single crystal layer has the same thickness as the insulating layer.

5. The germanium-on-insulator substrate of claim 1, wherein the oxide film has a second region recessed toward the bulk silicon substrate.

6. The germanium-on-insulator substrate of claim 5, wherein the thickness of the germanium single crystal layer is larger than the thickness of the insulating layer.

7. The germanium-on-insulator substrate of claim 1, wherein the top surface of the insulating layer and the top surface of the germanium layer are at the same level.

8. The germanium-on-insulator substrate of claim 1, wherein the first region has a width along a first direction parallel to a top surface of the bulk silicon substrate and a height along a second direction perpendicular to the first direction, and the width of the first region is less than the height of the first region.

9. A germanium-on-insulator substrate comprising:
a bulk silicon substrate;
an oxide film disposed on the bulk silicon substrate and having a first region exposing a portion of the bulk silicon substrate and a second region recessed toward the bulk silicon substrate;
a silicon layer covering a portion of a top surface of the oxide film;
a germanium layer grown onto the oxide film using the bulk silicon substrate exposed through the first region as a seed layer; and
an insulating layer disposed on the silicon layer,
wherein the germanium layer contacts the silicon layer.

10. The germanium-on-insulator substrate of claim 9, wherein the germanium layer comprises:
a growth layer filling the first region and contacting the bulk silicon substrate; and
a germanium single crystal layer connected to the growth layer and grown onto the oxide film.

11. The germanium-on-insulator substrate of claim 10, wherein the thickness of the germanium single crystal layer is larger than the sum of the thicknesses of the insulating layer and the silicon layer.

12. The germanium-on-insulator substrate of claim 9, wherein a top surface of the insulating layer and a top surface of the germanium single crystal layer are disposed on the same plane.

13. A method for forming a germanium-on-insulator substrate, the method comprising:
stacking an oxide film and a silicon layer in sequence on the bulk silicon substrate;
etching a portion of the silicon layer to expose a portion of the oxide film;
forming an insulating layer covering both the silicon layer and the exposed oxide film;
etching a portion of the insulating layer to expose a top surface of the oxide film;
etching the oxide film to expose a portion of the bulk silicon substrate; and
forming a germanium layer grown from the exposed bulk silicon substrate and disposed on the oxide film.

14. The method of claim 13, wherein the etching of the portion of the insulating layer comprises etching the insulating layer so as to form an etching width less than a width exposed by etching the silicon layer.

15. The method of claim 13, wherein the etching of the oxide film comprises etching a portion of the oxide film to form a first region exposing a portion of the bulk silicon substrate, and the height of the first region is larger than the width of the first region.

16. The method of claim 13, further comprising:
after the etching of the portion of the insulating layer, forming a second region having an etching width larger than a width exposed by etching the oxide film.

17. The method of claim 16, wherein the forming of the germanium layer comprises:
growing the germanium single crystal layer in the second region up to the same level as the top surface of the oxide film;
etching the insulating layer such that a side surface of the silicon layer and a sidesurface of the insulating layer are disposed on the same plane; and
growing the germanium single crystal layer at least up to a top surface of the insulating layer.

18. The method of claim 17, further comprising performing chemical mechanical polishing such that the top surface of the insulating layer and a top surface of the germanium single crystal layer are disposed at the same level.

19. The method of claim 13, wherein the forming of the germanium layer comprises depositing the germanium layer using a reduced pressure chemical vapor deposition process (RPCVD) or an ultra-high vacuum chemical vapor deposition (UHVCVD).

20. The method of claim 13, wherein the forming of the germanium layer comprises depositing the germanium layer at a deposition temperature between 400° C. and 700° C. using a mixed gas of GeH₄ and H₂, and the flow rate of the mixed gas of GeH₄ and H₂ is 10 sccm to 100 sccm.
